(19) United States
(12) Patent Application Publication
(10) Pub. No.: US 2026/0181819 A1
(43) Pub. Date: Jun. 25, 2026

(54) FLEXIBLE ORIENTATION FAN INTERCONNECT MODULE

(71) Applicant: HEWLETT PACKARD ENTERPRISE DEVELOPMENT LP, Spring, TX (US)

(72) Inventors: Chih-Wei Chiang, Taoyuan City (TW); Chui Ching Chiu, Taoyuan City (TW); Kuan-Wei Chen, Taipei City (TW)

(21) Appl. No.: 18/991,958

(22) Filed: Dec. 23, 2024

(51) Int. Cl. H05K 7/20

(52) U.S. Cl. CPC H05K 7/20172; H05K 7/20727

(57) ABSTRACT

A fan interconnect module for an information processing device comprises a housing. A fan connection connector is formed in the housing and may be configured to selectively receive an electrical connector of a fan module. A cable connection connector is further formed in the housing and be configured to selectively receive a first cable connector of a cable connected to a system board of the information processing device. The cable connection connector may be electrically connected to the fan connection connector and may have an insertion axis perpendicular to the insertion axis of the fan connection connector. The fan interconnect module may include first attachment features on a first side of the housing and configured to mount the fan interconnect module in a first orientation and second attachment features on a second side of the housing and configured to mount the fan interconnect module in a second orientation.

Information processing systems, (e.g., computers) generate heat during operation and, if the heat is not dissipated or cooling is not provided, damage can occur to various components within the system. One way of cooling is installing fans, where the fans are electrically connected at fan connection points on the motherboard. Once installed, the fans are able to provide the necessary cooling for the system.

### BRIEF DESCRIPTION OF THE DRAWINGS

The present disclosure can be understood from the following detailed description, either alone or together with the accompanying drawings. The drawings and related description of the figures are included to provide a further understanding of the present disclosure and are incorporated in and constitute a part of this specification. The drawings illustrate one or more nonlimiting aspects and implementations of the present teachings and together with the description explain certain principles and operation. In the drawings:

FIG. 1 is a block diagram of a system including a flexible orientation fan interconnect module.

FIG. 2 is a perspective view of a flexible orientation fan interconnect module.

FIG. 3 is a rear elevation view of a flexible orientation fan interconnect module.

FIG. 4 is a top view of a flexible orientation fan interconnect module.

FIG. 5 is a front elevation view of a flexible orientation fan interconnect module.

FIG. 6 is a bottom perspective view of a flexible orientation fan interconnect module.

FIG. 7 is a perspective view of a flexible orientation fan interconnect module with cables.

FIG. 8 is a rear perspective view of the flexible orientation fan interconnect module of FIG. 7.

FIG. 9 is a perspective view of a chassis having features to receive a flexible orientation fan interconnect module in a state of the fan interconnect module uninstalled.

FIG. 10 is a perspective view of a flexible orientation fan interconnect module installed in a chassis in a first orientation.

FIG. 11 is a top view of the installed flexible orientation fan interconnect module of FIG. 10.

FIG. 12 is a perspective view of a flexible orientation fan interconnect module coupled to a bracket in a second orientation.

FIG. 13 is a perspective view of the flexible orientation fan interconnect module of FIG. 12 with a fan.

FIG. 14 is a method for installing a fan in a system having a flexible orientation fan interconnect module.

### DETAILED DESCRIPTION

In many systems, the fans are installed in the system by attachment to a fan support that is coupled to the chassis of the system and by engagement of an electrical connector of the fan with an electrical connector on the primary system board of the system. In enterprise grade information processing systems (e.g., servers), the fans are often provided with fan guards which have a connector holder that holds the electrical connector of the fan in a predetermined position and orientation to allow it to mate with the electrical connector of the system board. This arrangement can allow for easy installation or removal of the fans, as the user does not have to worry about manually handling cables or connectors but can instead simply push or pull the fan to make the needed connections. In some cases, the arrangement may allow for blind-mating, which refers to mating that occurs automatically as the fans are installed without the user needing to see or manually align the connectors.

In other information processing systems, cables may be used to connect the fans to the system board rather than connecting the fans directly to the system board. Advantageously, the cables can provide the system designer with more flexibility in locating the fans.

However, the use of cables can sometimes make it harder for users to install/remove fans, as the simple mating that is enjoyed with the direct-to-board connection (e.g., blind-mating) is lost. In an attempt to regain the ease of installation, in some cases, the cables may be mounted to the chassis, for example using a specially designed holder, in a manner that simulates the direct-to-board connection. But one drawback of this approach is that the cables that can be used in this manner may need to have specially configured connectors, which may be more complicated and costly than standard cables, and a special cable holder may also be needed to hold the cables, which further adds to costs and complexity. Furthermore, because different systems may have different fan mounting arrangements, the cable and/or holder which may be used in one system may not be suitable for use in a different system. For example, in a rack-mount server, the fans and the cable connectors may be mounted to the base of the chassis and configured for mating along a vertical axis perpendicular to the base, whereas in a different tower server, a fan may be located on the outer face of the front panel of the chassis and may connect to the cable through an aperture in the front panel. These different configurations would require differently configured cables and/or differently configured holders. Accordingly, a manufacturer needs to design, manufacture, and handle multiple different versions of such cables and/or multiple different versions of the cable holders, which further drives of costs and complexity.

To address these and other issues, examples disclosed herein comprise a flexible orientation fan interconnect module which can be attached to a chassis of an information processing system to provide a fan connection point, which can be remote from the system board, at which a fan can be electrically connected to the system in an easy manner (e.g., via blind-mating). The fan interconnect module can be electrically connected to a system board via a cable, which allows for flexible positioning of the module at various locations in a chassis. In addition, the module is designed to be attachable to a variety of support structures in a variety of orientations, thus allowing the fan interconnect module to be deployed in different poses which can accommodate a variety of different fan mounting configurations. This ability to accommodate different fan mounting configurations at a variety of locations allows greater flexibility to system designers when trying to determine where and how fan mounting points should be provided. In addition, this ability to accommodate different fan mounting configurations and locations also can allow for the same fan interconnect module to be usable in multiple different systems having different fan mounting arrangements, without the need for designing multiple specialized cable holders or multiple specialized cables, thus greatly reducing costs and complexity.

The flexible orientation fan interconnect module may comprise a housing which can be attached to various different supports of the chassis (e.g., base, front panel, etc.) in multiple orientations, as well as two electrical connectors configured to electrically connect to the fan and a cable, thereby electrically interconnecting the fan with the cable. The flexible orientation fan interconnect module may have first attachment features which allow the module to be mounted to a first support of the chassis (e.g., the base) in a first orientation in which a fan connection connector faces away from the first support. The flexible orientation fan interconnect module may also have second attachment features which allow the module to be mounted to a second support of the chassis (e.g., the front panel) in a second orientation in which the fan connection connector faces towards the second support. Thus, the module can be used in multiple different fan mounting configurations, such as a first configuration in which the fans and the flexible orientation fan interconnect module are mounted to a base of the chassis and the fan's connector mates with the fan connection connector of the fan interconnect module along an insertion axis perpendicular to the base, and a second configuration in which the fans are mounted to an outer face of the front panel, the flexible orientation fan interconnect module is mounted on an inner face of the front panel, and the fan's connector extends through the front panel to mate with the fan connection connector of the flexible orientation fan interconnect module along an insertion axis perpendicular to the front panel. Thus, the need to design and produce different types of cable holders for these different fan mounting configurations can be avoided. Moreover, the same type of cable can be connected to the flexible orientation fan interconnect module in both configurations, thus avoiding the need to design custom cables for each of these two fan mounting configurations.

In some examples, the electrical connectors of the flexible orientation fan interconnect module are disposed at a ninety-degree angle with respect to one another. In use, one of the electrical connectors couples with a corresponding connector on a fan and the other electrical connector couples with a cable connector, which is in turn coupled to the system board at a board fan connector. The electrical connector of the module that is to be coupled to the fan in a particular configuration may be referred to as the fan connection connector and the electrical connector of the module that is to be coupled to the cable in a particular configuration may be referred to as the cable connection connector. In some examples, the two electrical connectors are different from one another in form factor, with one being designed specifically for connection to the fan and the other designed specifically for connection to the cable, and in such cases the one connector is always the fan connection connector while the other connector is always the cable connection connector. In other examples, the two electrical connectors may have similar form factors so that a fan can be connected to either one of the connectors and a cable can be connected to either one of the connectors, depending on the needs of the particular fan mounting configuration being implemented—i.e., one connector may serve as the fan connection connector in one fan mounting configuration but may serve as the cable connection connector in another fan mounting configuration. Because the electrical pins of the two electrical connectors of the module are in electrical contact with one another, when the fan and cable are connected to the module the module electrically interconnects the fan with the cable, i.e., the fan receives electrical signals from the system board via the cable and the interconnect module.

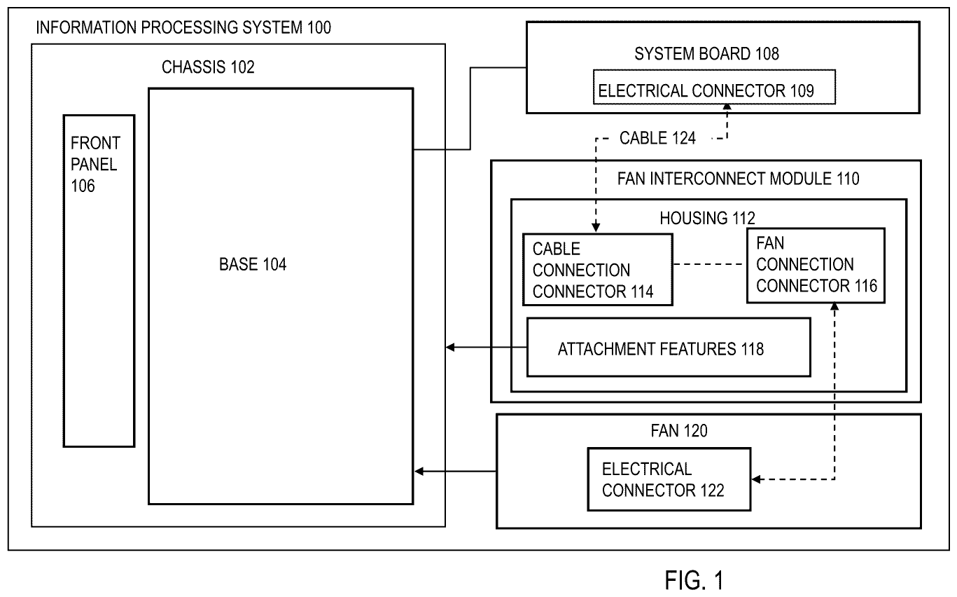

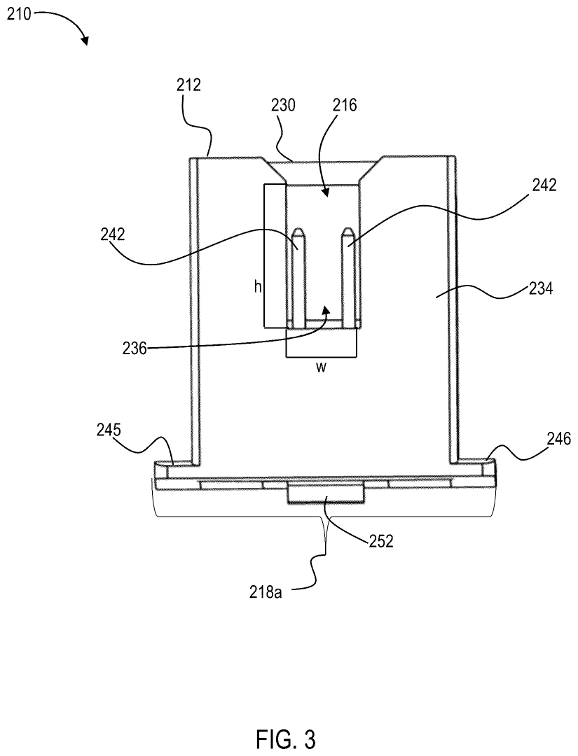

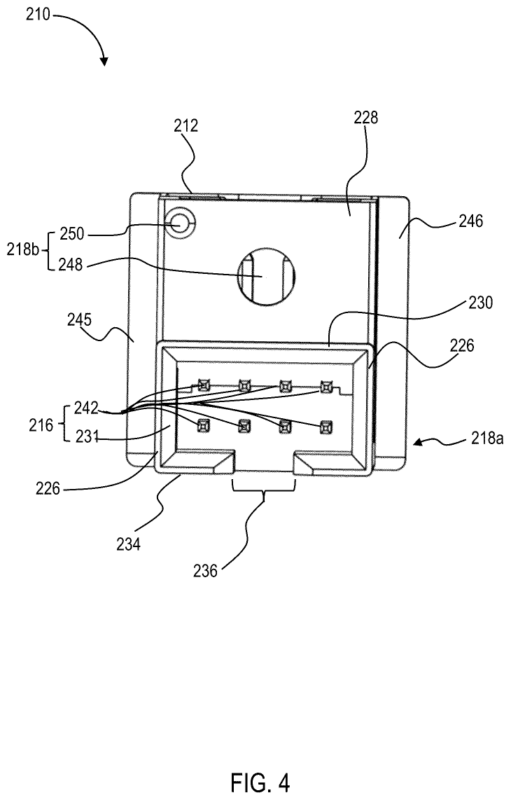

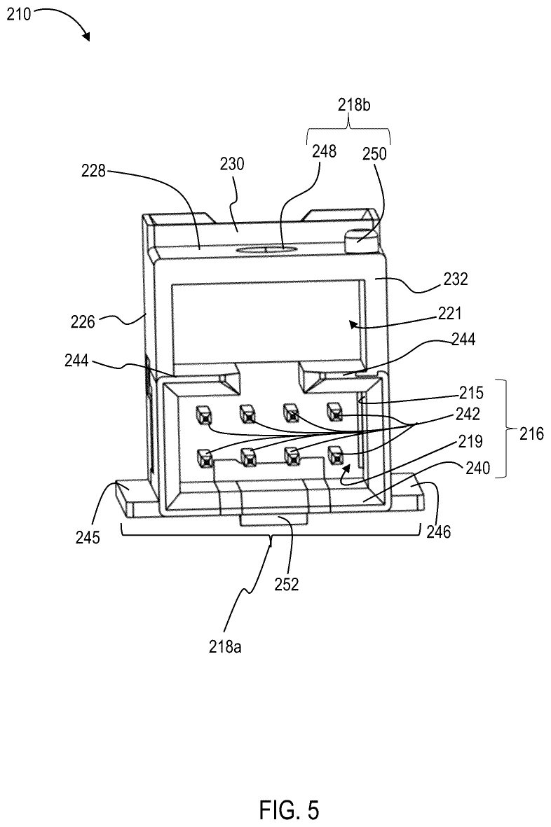

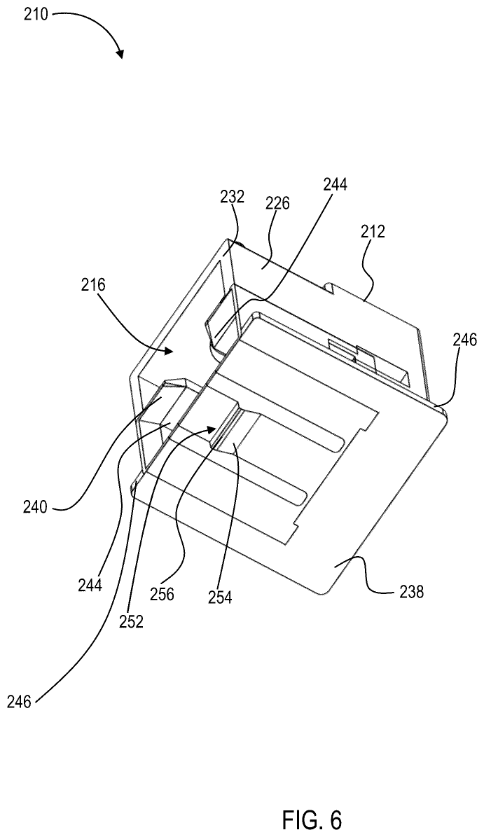

These and other examples will be described in greater detail below in relation to FIGS. 1-14.

FIG. 1 illustrates an example information processing system 100. FIG. 1 is schematic in nature, and it should be understood that FIG. 1 is not intended to illustrate specific shapes, dimensions, or other structural details accurately or to scale, unless otherwise noted herein. Implementations of information processing system 100 may have different numbers and arrangements of the illustrated components. In addition, components illustrated in FIG. 1 may be omitted from some examples disclosed herein, and components which are not illustrated in FIG. 1 may also be included in some examples disclosed herein. In FIG. 1, physical connections (e.g. physical attachment and/or support) between components are indicated conceptually by solid lines extending between the components, whereas electrical connections between components are indicated conceptually by broken (e.g., dashed) lines extending between the components. Furthermore, connections which may be intermittent or conditional (e.g., occurring in some states but not in others) are indicated by arrows, with dashed-line arrows indicating intermittent/conditional electrical connections and solid-line arrows indicating intermittent/conditional physical connections. The fan interconnect module 110 is illustrated in FIG. 1 in the context of the information processing system 100 to aid understanding, but some examples disclosed herein comprise the fan interconnect module 110 alone (i.e., not yet installed in any information processing system), and other examples comprise the information processing system 100 with the fan interconnect module 110 installed therein.

Information processing system 100 includes a chassis 102 which physically supports, and in some cases encloses or houses, the other components of the system 100. The chassis 102 may include a base 104 and a front panel 106. Chassis 102 may further include other structural members (not illustrated) such as a rear panel, side walls, a cover, etc.

Information processing system 100 further includes a system board 108, which may be supported by the base 104 of chassis 102. The system board 108 may include components such as a processor (not shown) and electrical connector 109, which are familiar to those or ordinary skill in the art and thus are not described in detail herein. The system board 108 may be a motherboard, a host processor module (HPM) board, or any other suitable board.

A flexible orientation fan interconnect module 110 may include a housing 112 and two electrical connectors formed in, or coupled to, the housing 112. These electrical connectors are also referred to herein as a cable connection connector 114 and a fan connection connector 116. The cable connection connector 114 is configured to mate and electrically connect with a cable 124, while the fan connection connector 116 is configured to mate and electrically connect with an electrical connector 122 of a fan 120. The cable connection connector 114 and the fan connection connector 116 are electrically connected together such that, when the cable 124 and the fan 120 are connected with the module 110, the module 110 electrically interconnects the cable 124 with the fan 120.

More specifically, each of connectors 114/116 may comprise a connector housing configured to mate with a complementary connector and electrical pins within the connector housing configured to contact and electrically connect with complementary pins of the complementary connector. The pins of the cable connection connector 114 are electrically connected with corresponding electrical pins of the fan connection connector 116 via circuitry (e.g., wires and/or a printed circuit board). In some examples, the connector housings of one or both of the connectors 114/116 may be distinct from the housing 112, in which case that connector 114/116 may be attached to the housing 112. In other examples, the connector housings of one or both of the connectors 114/116 may be integrally formed with the housing 112, i.e., a portion of the housing 112 also serves as the connector housing of that connector 112/116.

In some examples, the cable connection connector 114 and the fan connection connector 116 are different from one another in form factor. In other examples, the cable connection connector 114 and fan connection connector 116 may have the same of similar form factors. In some examples, the connectors 114 and 116 are formed in, or coupled to, the housing 112 at different orientations. Specifically, in some examples, the connectors 114 and 116 are oriented to face ninety-degrees apart from one another, meaning that an angle between an insertion axis of the connector 114 and an insertion axis for the connector 116 is ninety degrees. The insertion axis of a connector refers to an axis along which one or both of the connector and a complimentary connector need to translate during mating therebetween, with the insertion axis being determined by the geometry of the connector (e.g., where in the connector housing the opening is located, the orientations of the pins, etc.). As used herein, a direction in which a connector faces corresponds to a direction pointing away from the connector along the insertion axis thereof.

In addition, the flexible orientation fan interconnect module 110 may be configured to couple with (i.e., attach to) the chassis 102. More particularly, the fan interconnect module 110 may couple with the chassis 102 by attachment features 118 of the module 110. The attachment features 118 may include one or more features formed integrally with (i.e., as a unitary part of) the housing 112 and/or one or more features formed separately from and then attached to the housing 112. In some examples, attachment features 118 may allow coupling of the fan interconnect module 110 to the chassis 102 in multiple different mounting configurations. These different mounting configurations may include mounting at multiple different points in the chassis 102, mounting to different support structures, and/or mounting in different orientation. In some examples, the ability to couple the module 110 to the chassis 102 in multiple different mounting configurations may be accomplished through the use of multiple distinct sets of attachment features 118, with each set of attachment features 118 enabling a corresponding set of mounting configurations. For example, attachment features 118 may allow coupling of the fan interconnect module 110 to the base 104 directly or indirectly via an intermediary (e.g., a bracket) mounted on the base 104, which may correspond to a first mounting configuration, or to the front panel 106, which may correspond to a second mounting configuration. As another example, attachment features 118 may allow coupling of the fan interconnect module 110 to a support structure in a first orientation in which the fan connection connector 116 faces away from the support structure, or in a second orientation in which the fan connection connector 116 faces towards the support structure. In some examples, the first orientation may be used in the first mounting configuration (e.g., when mounting to the base) and the second orientation may be used in the second mounting configuration. In some examples, first attachment features out of the attachment features 118 are used in the first orientation/first mounting configuration and second attachment features out of the attachment features 118 are used in the second orientation/second mounting configuration. In some examples, the attachment features are formed in or attached to to one side of the housing 112 and the second attachment feature are formed in or attached to the opposite side of the housing 112.

Information processing system 100 further includes a fan 120. Fan 120 may be coupled to the base 104 of chassis 102 such that fan 120 is able to move air over the information processing system 100. Fan 120 may include an electrical connector 122 that, when coupled to a power source, provides power to the fan 120.

More particularly, the electrical connector 122 of fan 120 may be coupled to the fan connection connector 116 of the fan interconnect module 110. The cable connection connector 114 of the fan interconnect module 110 may be coupled to the system board 108 at electrical connector 109. The cable connection connector 114 may be coupled to the electrical connector 109 via a cable 124. Due to the electrical connection between the cable connection connector 114 and the fan connection connector 116, the fan connection connector 116 may provide electrical power to the fan 120 at the electrical connector 122 as a result of the electrical connection between the cable connection connector 114 and the electrical connector 109. As a result, the fan interconnect module 110 and/or the fan 120 may be located at differing positions and/or at different orientations within the information processing system 100.

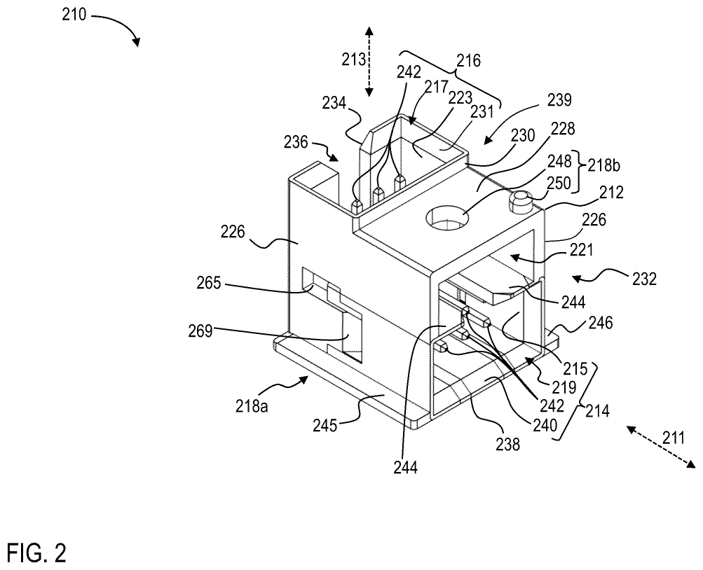

Turning now to FIGS. 2-13, an example of a fan interconnect module 210 that could be used in an information processing system such as system 100 is shown. Fan interconnect module 210 may be one implementation example of fan interconnect module 110 shown in and described with respect to FIG. 1 and may be used in a system such as information processing system 100, described with respect to FIG. 1. Fan interconnect module 210 thus comprises components which correspond to (i.e., are implementation examples of) components of the module cage 110, and the correspondence between such components is indicated herein by the components having reference numbers with the same last two digits, such as 126 and 226. Aspects of the fan interconnect module 110 and its components described above may also be applicable to the fan interconnect module 210 and its corresponding components, but the fan interconnect module 110 and its components are not limited to the fan interconnect module 210 and its components, which are just one example of how the fan interconnect module 110 may be implemented. In some instances, aspects of the fan interconnect module 110 already described above, which are also applicable to the fan interconnect module 210, are not described below to avoid duplicative description.

Fan interconnect module 210 comprises a housing 212, with the housing 212 further comprising a pair of side walls 226, a top wall 228, a rear wall 234, and a bottom wall 238. More particularly, the pair of side walls 226 may extend perpendicularly upward from the bottom wall 238 to a top side 229 of the housing 212, with the side walls 262 being generally parallel to one another. The top side 239 of the housing 212 comprises the top wall 228 and a connector opening 217 (described below). The top wall extends between the pair of side walls 226 substantially parallel to the bottom wall 238.The rear wall 234 may extend perpendicularly between the side walls 226 and from the bottom wall 238 to the top side 239. A front side 232 of the housing 212 may be disposed opposite from the rear wall 234, with the front side 232 comprising edges of the top wall 228, bottom wall 238, and side walls 236, as well as a connector opening 219 and an opening into a compartment 221, described in more detail below.

The top side 229 of the housing 212 may further include an upper ledge 230 extending from the top wall 228 to increase the profile of at least a portion of the top side 229. More particularly, the upper ledge 230 may partially encircle and form a rim of a connector opening 217 of the fan connection connector 216.

A cable connection connector 214 may be formed within housing 212. The cable connection connector 214 comprises a connector housing 215, a connector opening 219 leading into an interior space within the connector housing 215, and electrical pins 242 disposed in the space within connector housing 215. The connector housing is formed from portions of the housing 212, specifically: portions of the side walls 226, the bottom wall 238, and ledges 244 form the connector housing 215 and define an interior space therebetween. The connector opening 219 is formed in the front side 232 of the housing 212 and leads to the interior of the connector housing 215, such that a complementary connector can be received within the connector housing 215 via insertion through the opening 219. For example, the opening 219 may be configured to receive a cable connector such as first cable connector 260a.

The connector housing 215 of the cable connection connector 214 may further comprise a ramped lead in 240 encircling the rim of the opening 219 and formed in the edges of the bottom wall 238, side walls 226, and ledge 244. The lead in 240 is sloped so as to facilitate insertion of a connector such as cable connector 260a. More particularly, the ramped lead in 240 may assist in orienting and locating the first cable connector 260a as it is moved in the direction A along the insertion axis 211 of the connector 214 into engagement with the cable connection connector 214.

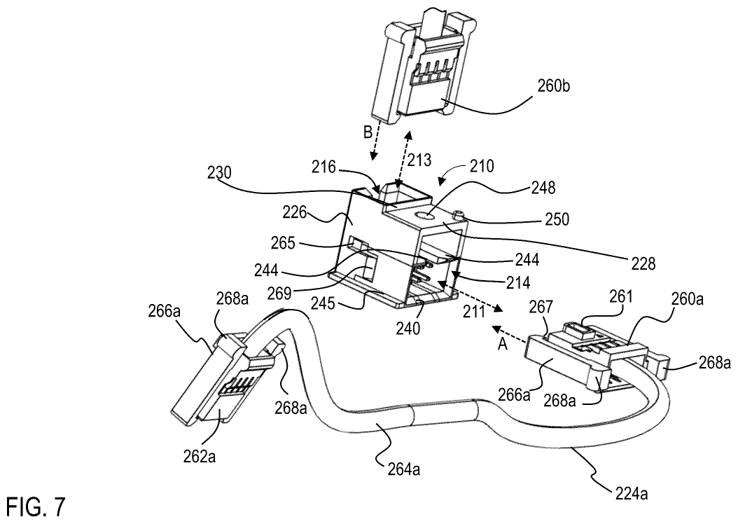

Additionally, cable connection connector 214 may further include a pair of ledges 244 coupled to each of the side walls 226 and forming a top boundary of the connector housing 215 of the cable connection connector 214. These ledges 244 also form the bottom boundary of a hollow compartment 221 which is located above the connector housing 215. The ledges 244 may be configured to engage with a top side of the first cable connector 260a. More particularly, as shown in FIG. 7, the first cable connector 260a, as well as the first fan connector 260b and second cable connector 262a, may include a locating tab 261 on a top side thereof. This locating tab 261 may slide into the gap between the pair of ledges 244, with this gap forming a groove or track along which the locating tab 261 slides during insertion.

As shown in FIG. 7, the first cable connector 260a, as well as the first fan connector 260b and second cable connector, 262a may also include a pair of deflectable side arms 266a, 266b. The deflectable side arms 266a, 266b may be deflectable through manual application of pressure at deflectable arm handles 268a, 268b at a proximal end of the arms 268a,268b, or by direct application of pressure to the distal end of the deflectable side arms 266a, 266b. In particular, during insertion of the connector 260a into the connector 214, the deflectable side arms 266a, 266b may engage with the side walls 226 which may deflect the distal ends of the deflectable side arms 266a, 266b outward. As insertion continues, the deflectable side arms 266a, 266b may travel along the outer surfaces of the side walls 226 until a latch hook 267a at the distal end of the deflectable side arms 266a, 266b reaches a latch slot 269 in the side wall 226, whereupon a spring force generated from the deflection of the arms 268a/268b may urge the distal ends of the arms 268a/268b inward, causing the latch hook 267 to enter the latch slot 269. In other words, the latch hooks 267 of the side arms 266a, 226b snap into engagement with the latch slot 269. This engagement secures the connector 260a in the connector 214, preventing withdrawal of the connector 260a without first deflecting the side arms 266a,266b to remove the latch hook 267 from the latch slot 269.

The cable connection connector 214 may include a plurality of electrical pins 242 disposed therein and extending towards the opening to allow mating with the first cable connector 260a. More particularly, as shown in FIG. 7, the first cable connector 260a may have an electrical pin receptacle 265. While FIG. 7 shows only the electrical pin receptacle 265 of the second cable connector 262b, it is to be understood that each of the first cable connectors 260a, and first fan connector 260b and each of the second cable connector 262a have an electrical pin receptacle 265. As first cable connector 260a is moved in direction A along insertion axis 211, the electrical pin receptacle 265 engages with the electrical pins 242. Thus, when first cable connector 260a is fully received within the cable connection connector 214, the electrical pins 242 are engaged with the electrical pin receptacle 265.

As shown in FIG. 7 and FIGS. 12-13, when the first cable connector 260a of first cable 224a is engaged with the cable connection connector 214, the second cable connector 262a of the first cable 224a remains unattached. The second cable connector 262a of the first cable 224a may be coupled with another component of the system. For example, as discussed with respect to FIG. 1, the cable connection connector 214 may be coupled with an electrical connector provided as part of a system board. More particularly, in the context of FIG. 7 and FIGS. 12-13, the second cable connector 262a of the first cable 224 may couple with a system board electrical connector (not shown), allowing the fan interconnect module 210 to receive power from the system board.

The fan interconnect module 210 may further include a fan connection connector 216 formed within housing 212. The fan connection connector 216 comprises a connector housing 223, a connector opening 217 leading into an interior space within the connector housing 223, and electrical pins 242 disposed in the space within connector housing 223. The connector housing 223 is formed from portions of the housing 212, specifically: portions of the upper ledge 230, the top wall 228, the rear wall 234, and the side walls 226.The connector housing 223 defines an open volume between these walls to receive a first fan connector 260b, with a connector opening 217 leading into this open volume. The fan connector 260b is a connector of a fan (not illustrated). The fan connector 260b may be connected directly to the fan as an integral part thereof, or it may be part of a separate cable which is removably coupled to the fan. In some examples, the fan connector 260b is attached to a fan guard of the fan which holds the fan connector 260b in a predetermined orientation to allow for blind mating. In some examples, the connector housing 223 is oriented to facilitate this blind mating in certain fan mounting configurations. The connector opening 217 is formed in a top side 239 of the housing 219, with the upper ledge 230 encircling and forming the rim of the connector opening 217. The rear wall 234 may include a cutout 236 having a height h and a width w. The cutout 236 is configured to receive the locating tab 261 formed in the top side of the first fan connector 260b to aid in aligning and guiding the connector into a proper installation position. As such, the height h and the width w may be sized to engage with the tab 261 of the first fan connector 260b. Connector housing 223 may also comprise a ramped lead-in surface 231 similar in form and function to the ramped lead-in surface 240.

The housing 212 may also comprise latch slots 265 arranged to receive latch hooks 267 of the arms 268 of a connector 260b mated to connector 216. The latch hooks 267 may engage the latch slots 265 in a similar fashion as described above in relation to latch slots 269.

As with the cable connection connector 214, the fan connection connector 216 may include a plurality of electrical pins 242 to engage with a corresponding electrical pin receptacle 265 of the first fan connector 260b. Thus, as the first fan connector 260b is moved in direction B along insertion axis 213, the electrical pin receptacle 265 therein engages with the electrical pins 242 of the fan connection connector 216.

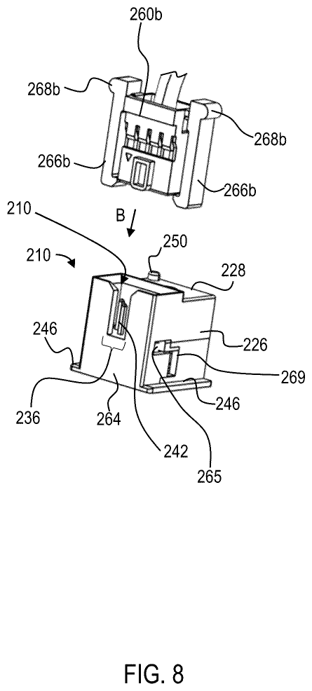

As shown in FIGS. 7 and 8, the first cable connector 260a, is part of a cable 224a. Cable 224a may correspond to a cable configured to engage with the fan interconnect module 210 at the cable connection connector 214 and to a system board. More particularly, a first cable connector 260a may be configured to couple with the cable connection connector 214 via insertion along insertion axis 211. Cable 224a, may include second cable connectors 262a. Second cable connector 262a may be separated from first cable connector 260a by a flexible wire portion 264a. As a result, cable connection connector 214 may be coupled to another system component, such as an electrical connector 109 of a system board, discussed with respect to FIG. 1, via the cable 224a, as discussed previously.

Similarly, the fan connection connector 216 may be coupled to a component such as a fan 120, discussed with respect to FIG. 1, via the fan connector 260b. The fan connector 260b may be part of a cable which is connected to the fan, or the fan connector 260b may be directly connected to the fan without any intervening cable. Because the fan connection connector 216 is electrically connected with the cable connection connector 214, coupling of the cable connection connector 214 with an electrical connector may provide power to the fan coupled to the fan connection connector 216. However, examples are not so limited and other connections are discussed further herein.

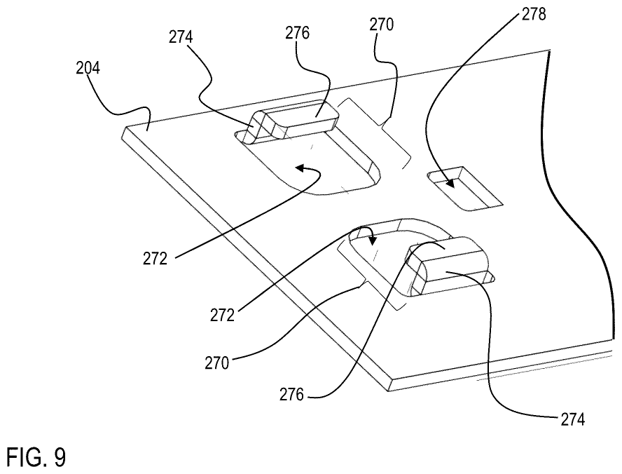

Returning to FIGS. 2-13, the fan interconnect module 210 may include first attachment features 218a, which may be formed as part of the bottom wall 238. More particularly, the first attachment features 218a may include a pair of flanges 246 protruding from the bottom wall 238 of the housing 212 to extend the bottom wall 238 beyond the side walls. The first attachment features 218a may further include a cantilevered latch 252, which may comprise a ramped portion 254 culminating at an apex 256. The first engagement features 218a may be configured to engage with corresponding engagement features in a chassis base 204, shown in FIG. 9. Although FIG. 9, shows the corresponding engagement features directly in the chassis base 204, examples are not so limited and the corresponding engagement features may be formed as part of a bracket that is separate from, but able to be coupled with, the chassis base 204.

More particularly, the complimentary engagement features comprise a pair of retention hooks 270 configured to receive the flanges 246. Each retention hook 270 may include an opening 272, a vertical portion 274 extending upwardly from the chassis base 204, and a flange engagement hook 276 extending over a portion of the opening 272. In addition, a latch receiving recess 278 is formed in the chassis base 204.

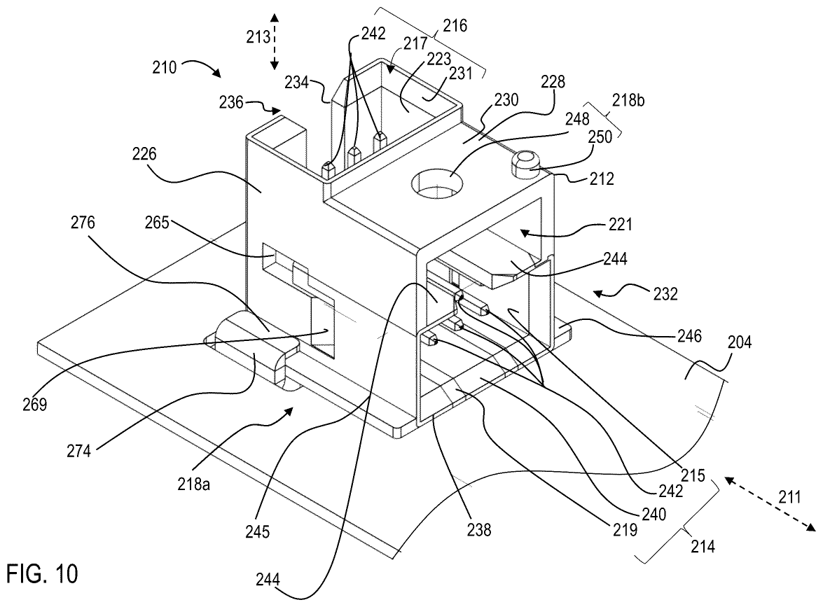

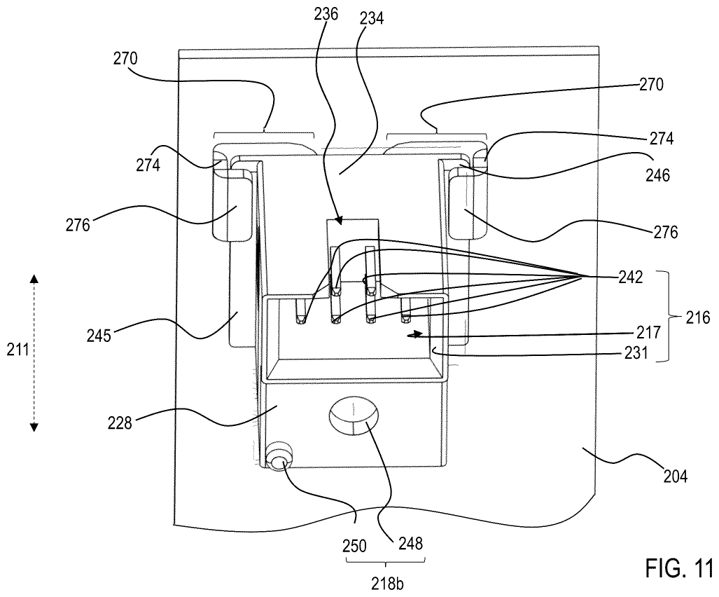

As shown in FIGS. 10-11, the first engagement features 218a of the fan interconnect module 210 can be engaged with the retention hooks 270 and the latch receiving recess 278 to couple the fan interconnect module 210 with the chassis base 204 in a first orientation. More particularly, the housing 212 of the fan interconnect module 210 may be slid in a direction parallel to the chassis base 204 towards the retention hooks 270 and the latch receiving recess 278. Due to the deflectable nature of cantilevered latch 252, the apex 256 of cantilevered latch 252 may be urged towards the bottom wall 238 as the fan interconnect module 210 is moved, with ramped portion 254 moving to be substantially parallel with the bottom wall 238. As flanges 246 move towards the retention hooks 270, the flanges slidingly engage with the vertical portion 274 and the flange engagement hook 276, aiding in locating the fan interconnect module 210 on the chassis base 210 by preventing undesired horizontal and vertical movement. The fan interconnect module 210 is then able to continue moving with respect to the chassis base 204 until the cantilevered latch 252 reaches the latch receiving recess 278. Once the cantilevered latch 252 passes into the latch receiving recess 278, the apex 256 moves into an undeflected position (i.e., the apex 256 is no longer urged towards the bottom wall 238) and drops into the latch receiving recess 278. In this manner, the fan interconnect module 210 is installed in a first orientation, shown in FIGS. 10-11. In this first orientation, the insertion axis 211 of the cable connection connector 214 is parallel to the chassis base 204, while the insertion axis 211 of the fan connection connector 216 is perpendicular to the chassis base 204.

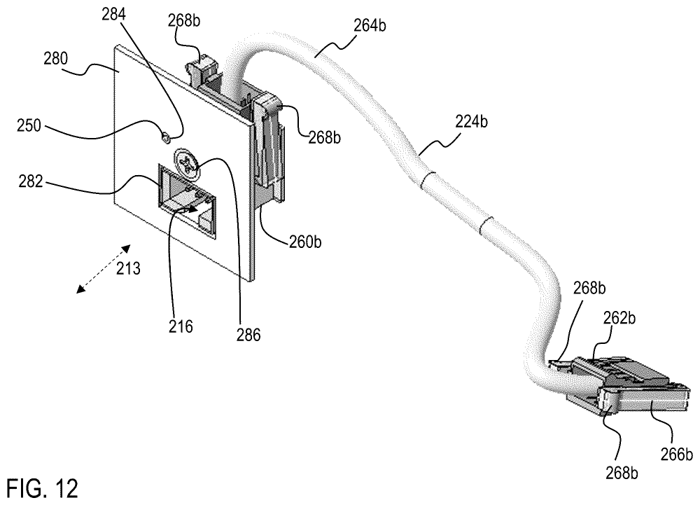

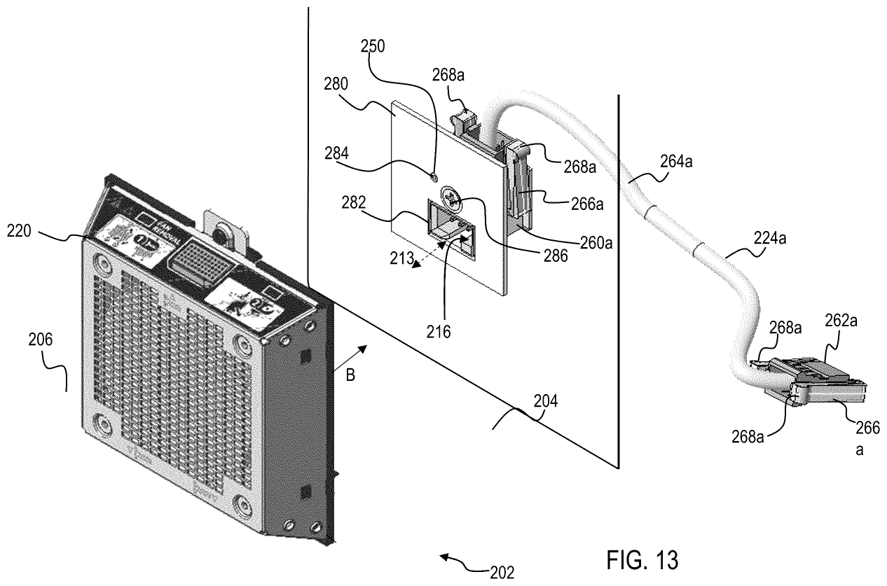

Fan interconnect module 210 may further include second engagement features 218b, which may be formed as part of top wall 228. Second engagement features 281b may have a different form than first engagement features 218a. In some examples, second engagement features 218b may comprise a screw hole 246 extending through the top wall 228 and a locating pin 250 extending from the top wall 228. Second engagement features 218b may be configured to engage with a bracket, such as bracket 280 shown in FIGS. 12-13, and more particularly at complementary engagement features formed as part of the bracket 280. This engagement may allow mounting of the fan interconnect module 210 to a location other than the chassis base 204. For example, bracket 280 may be mounted to a front panel 206 of a chassis 202. More particularly, the fan interconnect module 210 may be coupled to a rear face of the front panel 206. Thus, use of second engagement feature 218b allows the fan interconnect module 210 to engage with the chassis 202 in a second orientation that is different than the first orientation shown in FIGS. 10-11.

As shown in FIGS. 12-13, bracket 280 includes an opening 282 formed therein, with the opening 282 configured to allow access to fan connection connector 216. A recess 284 is disposed in bracket 280 and located such that locating pin 250 is receivable by the recess 284, ensuring alignment of the opening 282 and the fan connection connector 216 and providing a point of primary engagement. Once the locating pin 250 is engaged with the recess 284, a screw 286 may be inserted through a hole in the bracket 280 that corresponds to screw hole 248 of the second engagement features 218b. The screw 286 may be used to fix the fan interconnect module 210 to the bracket 280, allowing bracket 280 to be installed within the system without movement of the fan interconnect module. More particularly, as shown in FIG. 13, the bracket 280, with the fan interconnect module 210 installed therein, may be installed on front panel 206. Although FIG. 13 shows the bracket 280 in a state of being uninstalled with the front panel 206, the bracket may be coupled to a rear face of the front panel 206.

As shown in FIGS. 12-13, when the fan interconnect module 210 is installed in the second orientation (i.e., when second engagement features 218b are engaged) the insertion axis B of the fan connection connector is perpendicular to the front panel 206. More particularly, FIG. 13 shows a fan 220 coupled to a chassis 202 at a front panel 206 thereof. In some examples, the fan 220 may be coupled to a front face of the front panel 206. Further, while not shown in FIG. 13, fan 220 includes an electrical connector, such as electrical connector 122 discussed with respect to FIG. 1. The electrical connector may extend through an aperture in the front face of the front panel 206, allowing the electrical connector to extend through the front panel 206. This electrical connector may be configured to engage with the fan connection connector 216. More particularly, the fan connection connector 216 may be mated with the electrical connector. Once in the mated position, bracket 280 may be coupled to the rear face of front panel 206, fixing fan interconnect module 210 into a position whereby the fan connection connector 216 is mated with fan 220.

FIGS. 12-13 further show a cable 224a with a first cable connector 260a in an engaged state with the fan interconnect module 210. As described previously, first cable connector 260a is part of a cable 224a, with cable 224a further having a second cable connector 262a separated from the first cable connector 260a by a flexible wire portion 264a. Second cable connector 262a may be coupled to a system component, such as an electrical connector (not shown in FIGS. 12-13). Because the fan connection connector 216 is electrically coupled with the cable connection connector 214 into which first cable connector 260a is inserted, when bracket 280 is installed on front panel 206, and fan 220 is coupled with fan interconnect module 210 at the fan connection connector 216, the fan 220 may receive power through the fan interconnect module 210, allowing fan 220 to provide cooling to other components.

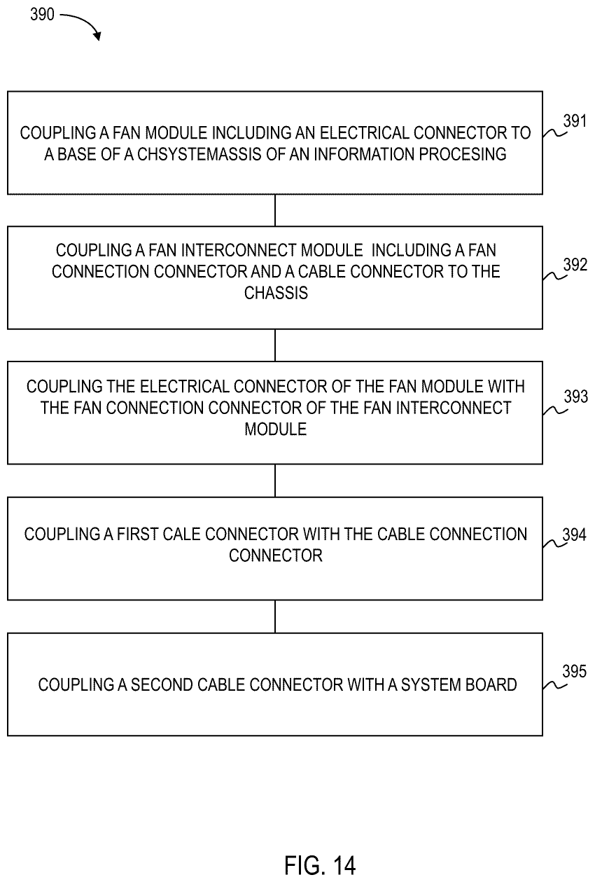

FIG. 14 is an example method 390 for installing a fan in an information processing system. At 391, method 390 includes coupling a fan module to a base of a chassis of an information processing system. The fan may be akin to fan 120, described with respect to FIG. 1, and may include an electrical connector, such as electrical connector 122, also described with respect to FIG. 1.

At 392, method 390 includes coupling a fan interconnect module to the chassis of the information processing system. As described with respect to FIGS. 2-13, the fan interconnect module may include a cable connection connector and a fan connection connector. In addition, as described with respect to FIGS. 2-13, the fan interconnect module may include engagement features formed as part of the fan interconnect module. Thus, in some examples, coupling the fan interconnect module to the chassis of the information processing system comprises engaging engagement features of the fan interconnect module with complimentary engagement features on the chassis. For example, as described with respect to FIGS. 9-11, a chassis may have features formed therein which are designed to interface with engagement features of the fan interconnect module, allowing the fan interconnect module to directly couple with the chassis.

In other examples, coupling a fan interconnect module to the chassis of the information processing system at 392 may include coupling engagement features of the fan interconnect module with complimentary engagement features of a bracket. For example, as described with respect to FIGS. 12-13, a bracket may include features to interface with the fan interconnect module. In such examples, once the fan interconnect module is coupled with the bracket, the bracket may then be coupled to the chassis. Thus, in such examples, the fan interconnect module may be coupled to the chassis via the bracket.

At 393, method 390 includes coupling the electrical connector of the fan module with the fan connection connector of the fan interconnect module. In some examples, the electrical connector of the fan module may be coupled with the fan connection connector by a cable, as described with respect to FIGS. 7-8. In other examples, such as those described with respect to FIGS. 12-13, the electrical connector of the fan module may be directly coupled with the fan interconnect module.

At 394, method 390 includes coupling a first cable connector with the cable connection connector of the fan interconnect module. As described with respect to FIGS. 2-13, the first cable connector may be inserted into the cable connection connector and be received therein such that the first cable connector engages with electrical pins of the cable connection connector.

At 395, method 390 includes coupling a second cable connector with a system board supported by the chassis. More particularly, the second cable connector may be coupled to an electrical connector of the system board. The second cable connector may be separated from the first cable connector but coupled thereto by a flexible wire portion, allowing transfer of electrical signals between the electrical connector of the system board to the cable connection connector. As described with respect to FIGS. 1-13, the cable connection connector may be electrically connected with the fan connection connector. Thus, when the second cable connector is coupled with the system board at 395, the fan, coupled to the fan connection connector by the electrical connector of the fan at 393, may receive electrical signals via the electrical connection between the fan connection connector and the cable connection connector.

It is to be understood that both the general description and the detailed description provide example implementations that are explanatory in nature and are intended to provide an understanding of the present disclosure without limiting the scope of the present disclosure. Other examples in accordance with the present disclosure will be apparent to those skilled in the art based on consideration of the disclosure herein. For example, various mechanical, compositional, structural, electronic, and operational changes may be made to the disclosed examples without departing from the scope of this disclosure, including for example the addition, removal, alteration, substitution, or rearrangement of elements of the disclosed examples, as would be apparent to one skilled in the art in consideration of the present disclosure. Moreover, it will be apparent to those skilled in the art that certain features or aspects of the present teachings may be utilized independently (even if they are disclosed together in some examples) or may be utilized together (even if disclosed in separate examples), whenever practical. In some instances, well-known circuits, structures, and techniques have not been shown or described in detail in order not to obscure the examples. Thus, the following claims are intended to be given their fullest breadth, including equivalents, under the applicable law, without being limited to the examples disclosed herein.

References herein to examples, implementations, or other similar references should be understood as referring to prophetic or hypothetical examples, rather than to devices/systems that have been actually produced, unless explicitly indicated otherwise. Similarly, references to qualities or characteristics of examples should be understood as representing the educated estimates or expectations of the inventors based on their understanding of the relevant principles involved, application of theory and/or modeling, and/or past experiences, rather than as being representations of the actual qualities or characteristics of an actually produced device/system or the empirical results of tests actually carried out, unless explicitly indicated otherwise.

Further, spatial, positional, and relational terminology used herein is chosen to aid the reader in understanding examples of the invention but is not intended to limit the invention to a particular reference frame, orientation, or positional relationship. For example, spatial, positional, and relational terms such as “up”, “down”, “lateral”, “beneath”, “below”, “lower”, “above”, “upper”, “proximal”, “distal”, and the like may be used herein to describe directions or to describe one element's or feature's spatial relationship to another element or feature as illustrated in the figures. These spatial terms are used relative to reference frames in the figures and are not limited to a particular reference frame in the real world. Furthermore, if a different reference frame is considered than the one illustrated in the figures, then the spatial terms used herein may need to be interpreted differently in that different reference frame. Moreover, the poses of items illustrated in the figure are chosen for convenience of illustration and description, but in an implementation in practice the items may be posed differently.

In addition, the singular forms “a”, “an”, and “the” are intended to include the plural forms as well, unless the context indicates otherwise. Moreover, the terms “comprises”, “comprising”, “includes”, and the like specify the presence of stated features, steps, operations, elements, and/or components but do not preclude the presence or addition of one or more other features, steps, operations, elements, components, and/or groups. Components described as coupled may be electronically or mechanically directly coupled, or they may be indirectly coupled via one or more intermediate components, unless specifically noted otherwise.

And/or: Occasionally the phrase “and/or” is used herein in conjunction with a list of items. This phrase means that any combination of items in the list—from a single item to all of the items and any permutation in between—may be included. Thus, for example, “A, B, and/or C” means “one of {A}, {B}, {C}, {A, B}, {A, C}, {C, B}, and {A, C, B}”.

Mathematical and geometric terms are not necessarily intended to be used in accordance with their strict definitions unless the context of the description indicates otherwise, because a person having ordinary skill in the art would understand that, for example, a substantially similar element that functions in a substantially similar way could easily fall within the scope of a descriptive term even though the term also has a strict definition. Moreover, unless otherwise noted herein or implied by the context, when terms of approximation such as “substantially,” “approximately,” “about,” “around,” “roughly,” and the like, are used, this should be understood as meaning that mathematical exactitude is not required and that instead a range of variation is being referred to that includes but is not strictly limited to the stated value, property, or relationship. In particular, in addition to any ranges explicitly stated herein (if any), the range of variation implied by the usage of such a term of approximation includes at least any inconsequential variations and also those variations that are typical in the relevant art for the type of item in question due to manufacturing or other tolerances. In any case, the range of variation may include at least values that are within ±1% of the stated value, property, or relationship unless indicated otherwise.

What is claimed is:

1. A fan interconnect module for an information processing device, comprising:
a housing;
a fan connection connector formed in the housing and configured to selectively receive an electrical connector of a fan module of the information processing device;
a cable connection connector electrically connected to the fan connection connector and configured to selectively receive a first cable connector of a cable, wherein:
the first cable is connected to a system board of the information processing device; and
the cable connection connector has an insertion axis perpendicular to an insertion axis of the fan connection connector;
first engagement features on a first side of the housing and configured to mount the fan interconnect module to a base of a chassis of the information processing device in a first orientation in which the insertion axis of the fan connection connector is perpendicular to the first support and the fan connection connector faces away from the first support; and
second engagement features on a second side of the housing and configured to mount the fan interconnect module to a panel of the chassis in a second orientation in which the insertion axis of the fan connection connector is perpendicular to the second support and the fan connection connector faces towards the panel.

2. The fan interconnect module of claim 1, wherein the first support is a base of the chassis and the second support is a front panel of the chassis.

3. The fan interconnect module of claim 1, wherein the first and second engagement features have different forms than one another.

4. The fan interconnect module of claim 3, wherein the first engagement features comprise a pair of flanges protruding from the housing and configured to slidingly engage with retention hooks on the base by sliding of the housing along a direction parallel to the base.

5. The fan interconnect module of claim 4, wherein the first engagement features further comprise a cantilevered latch configured to engage a recess in the base as the flanges engage the retention hooks to lock the fan interconnect module into the base.

6. The fan interconnect module of claim 3, wherein the second engagement features comprise a screw hole configured to receive a screw extending through the panel along a direction perpendicular to the panel.

7. The fan interconnect module of claim 6, wherein the second engagement features further comprise a locating pin configured to engage with a recess in the panel.

8. An information processing system, comprising:
a chassis comprising a base;
a system board supported by the base;
the fan interconnect module of claim 1 mounted to the base in the first orientation;
a fan supported by the base and comprising an electrical connector connected to the fan connection connector; and
a cable connected to the system board and to the cable connection connector of the fan interconnect module.

9. The information processing system of claim 8, further comprising a bracket coupled to the base, wherein the first engagement features engage with complementary engagement features on the bracket.

10. An information processing system, comprising:
a chassis comprising a base and a front panel;
a system board supported by the base;
the fan interconnect module of claim 1 mounted to a rear face of the front panel in the second orientation;
a fan mounted to a front face of the front panel and comprising an electrical connector extending through an aperture in the front panel and connected to the fan connection connector; and
a cable connected to the system board and to the cable connection connector of the fan interconnect module.

11. The information processing system of claim 10, further comprising a bracket coupled to the rear face of the front panel, wherein the second engagement features engage with complementary engagement features on the bracket.

12. An information processing system, comprising:
a chassis comprising a base and a front panel;
a system board supported by the base;
a fan interconnect module configured to couple with the chassis, the fan interconnect module further comprising:
a housing;
a fan connection connector formed in the housing; and
a cable connection connector electrically connected to the fan connection connector; and
a fan supported by the base and comprising an electrical connector connected to the fan connection connector.

13. The information processing system of claim 12, further comprising:
a first cable configured to selectively couple with the fan connection connector of the fan interconnect module at a first cable connector, wherein a second cable connector of the first cable is coupled to the fan at the electrical connector of the fan; and
a second cable configured to selectively couple with the cable connection connector at a first cable connector, wherein a second cable connector of the second cable is coupled to the system board of the information processing system.

14. The information processing system of claim 12, wherein the fan interconnect module further comprises:
first attachment features on a first side of the housing, wherein the first attachment features are configured to couple the fan interconnect module with the chassis in a first orientation; and
second attachment features on a second side of the housing, wherein the second attachment features are configured to couple the fan interconnect module with the chassis in a second orientation.

15. The information processing system of claim 14, wherein, in a state of the fan interconnect module coupled to the chassis in the first orientation, the fan interconnect module is coupled to the base of the chassis such that an insertion axis of the cable connection connector is parallel to the base of the chassis and an insertion axis of the fan connection connector is perpendicular to the base of the chassis.

16. The information processing system of claim 14, wherein, in a state of the fan interconnect module coupled to the chassis in the second orientation, the fan interconnect module is coupled to the front panel of the chassis such that an insertion axis of the fan connection connector is perpendicular to the front panel.

17. A method of installing a fan in an information processing system, comprising:
coupling a fan module to a base of a chassis of the information processing system, wherein the fan module comprises an electrical connector;
coupling a fan interconnect module to the chassis of the information processing system, wherein the fan interconnect module further comprises a fan connection connector and a cable connection connector;
coupling the electrical connector of the fan module with the fan connection connector of the fan interconnect module;
coupling a first cable connector with the cable connection connector of the fan interconnect module; and
coupling a second cable connector with a system board supported by the chassis, wherein the first cable connector is separated from the second cable connector by a flexible wire portion.

18. The method of claim 17, wherein coupling the electrical connector of the fan module with the fan connection connector comprises coupling the electrical connector and the fan connection connector via a cable.

19. The method of claim 17, wherein coupling the fan interconnect module with the chassis further comprises engaging engagement features on the fan interconnect module with complementary engagement features on the chassis.

20. The method of claim 17, wherein coupling the fan interconnect module with the chassis further comprises:
coupling engagement features of the fan interconnect module with complementary engagement features of a bracket; and
coupling the bracket to the chassis.
